(19) United States
(12) Patent Application Publication
(10) Pub. No.: US 2023/0170268 A1
(43) Pub. Date: Jun. 1, 2023

(54) Method and Apparatus for Achieving Package-Level Chip-Scale Packaging that Allows for the Incorporation of In-Package Integrated Passives

(71) Applicant: Atlas Magnetics Inc., Reno, NV (US)

(72) Inventor: John Othniel McDonald, Reno, NV (US)

(21) Appl. No.: 18/072,686

(22) Filed: Nov. 30, 2022

Related U.S. Application Data
(60) Provisional application No. 63/284,487, filed on Nov. 30, 2021.

(51) Int. Cl. H01L 23/31; H01L 23/00; H01L 21/56; H01L 21/78

(52) U.S. Cl. CPC H01L 23/3114; H01L 24/13; H01L 21/561; H01L 21/78; H01L 24/05; H01L 2224/0401; H01L 2224/13147

(57) ABSTRACT

A new method and apparatus for wafer-level electroplating that allows for the plating of pillars, inductors, windings, and other components not easily plated in plating wafer level chip scale packaging with ball connectors. By plating pillars directly onto a silicon wafer, covering both pillar and wafer with dielectric film, and grinding to expose the copper pillar, integrated circuits which incorporate passive components can be directly created on the wafer before any singulation.

### BACKGROUND

The field of the invention relates to semiconductor manufacturing relates to manufacturing integrated circuits and the associated packaging, and more specifically, it relates to chip scale packages.

Chip Scale Packaging (CSP) is a type of packaging that removes the need for traditional epoxy plastic encapsulation and instead uses the die itself as the edge of the component and the connections (pins) to the PCB limited to the surface of the die. Wafer Level-CSP (WL-CSP) is a method of producing chip scale packages. In general, for WL-CSP, as shown in FIG. 1, dice are prepared on a wafer, a metal or redistribution layer is prepared, and the dice are bumped—gaining solder ball connectors. Only after bumping is each die diced and prepared for shipping to the customer.

WL-CSP reduces the number of manufacturing steps and, thus, the associated cost of producing packaged chips when compared to traditional methods of packaging. As a low-cost minimalist packaging technology, WL-CSP is finding ever-wider adoption in the industry.

However, WL-CSP has several limitations. The first limitation is derived from the reliance on relatively large solder balls vs traditional silicon bonding pads. The size of the WL-CSP packaging is directly related to the number, pitch, and spacing of the solder balls. All soldier balls have a minimum spacing requirement ranging from 0.5 mm in the mid-market to approximately 0.22 mm on the leading edge at the time of this writing.

The spacing requirements may result in a silicon die being what is called “Solder ball limited” so that, in some cases, the silicon circuitry is significantly smaller than the final die size because a certain number of solder ball connections were needed for that die, and those connections were subject to the spacing requirement—expanding the die size beyond the circuit area. Conversely, in some cases, the silicon circuitry is larger than the minimum area for the solder balls, and this results in the silicon die size being limited by the silicon circuitry (i.e., being “core limited”).

The second limitation of WL-CSP methods is that they limit the package layers you can place as connections pass directly from the silicon die to the printed circuit board (PCB), preventing the integration of passives, for example. Occasionally an intervening redistribution layer (RDL) is placed between the silicon die and the solder ball to aid with the silicon die layout and solder ball location. Additional layers are not created on this RDL. This is to preserve the direct connection between the integrated circuit and the solder balls as well as to increase the package's susceptibility to warping.

Therefore, WL-CSP is not suited for in-package integrated passives. Integrated passives must already be manufactured on the surface of the silicon wafer before starting the relatively simple WL-CSP packaging process. On the other hand, standard multiple-layer substrate semiconductor packaging is increasingly being used for the integration of RF inductors, power redistribution, and system-in-package modules where multiple discrete passives are placed before over-molding.

The third limitation of WL-CSP is vibration resistance, as standard multiple-layer substrate packaging processes produce results that are more resistant to vibrations, making them a preferred choice in semiconductor products for the automotive industry.

The fourth limitation of WL-CSP is light susceptibility and thus requires additional processing for light immunity in many applications.

The fifth limitation of WL-CSP is that due to manufacturing constraints, WL-CSP IC components typically have a low resistance to warping due to differing coefficients of thermal expansion among the materials of each layer. This plays a significant role in limiting the WL-CSP direct die to PCB connections.

Warping also significantly limits use, as when the WL-CSP components are exposed to temperature swings, the varying layers expand at greatly different rates, which bends and may break the WL-CSP IC components. During the manufacturing process, any bending due to thermal expansion can greatly reduce the yield of components. However, placing material that could restrain warpage into the package is thought to interfere with the magnetic properties of the components.

However, despite the downsides, WL-CSP is an affordable and elegant packaging technology requiring only low-cost post-processing. No lead frames or wire bonds, which are often associated with standard semiconductor packages, are required for WL-CSP.

Standard semiconductor packages, which are larger, continue to exist because, in some cases, it is more cost-effective to design for the smallest silicon area possible and package in the smallest package. In many cases, WL-CSP does not produce the smallest possible packages due to the aforementioned solder ball limit.

In other cases, other semiconductor packages continue to exist for better reliability, the ability to place discrete passives in the same package/module, and also simply for production lines that are not able to support WL-CSP technology.

The following papers are incorporated by reference in full:

Clearfield, Howard M., et al. “Wafer-level chip scale packaging: benefits for integrated passive devices.” IEEE transactions on advanced packaging 23.2 (2000): 247-251.

Carpenter NiFe (36:64, ±5%) 36 Alloy: Technical Datasheet. (2014), Carptenter Technology Corporation.

Garrou, Philip. “Wafer level chip scale packaging (WL-CSP): An overview.” IEEE Transactions on Advanced Packaging 23.2 (2000): 198-205.

Lyon, K. G., et al. “Linear thermal expansion measurements on silicon from 6 to 340 K.” Journal of Applied Physics 48.3 (1977): 865-868.

Toepper, Michael. “Wafer level chip scale packaging.” Materials far Advanced Packaging. Springer, Cham, 2017. 627-695.

Yoon, Seung Wook. “Challenges and improvement of reliability in advanced wafer level packaging technology,” 2016 IEEE 23rd International Symposium on the Physical and Failure Analysis of Integrated Circuits (IPFA). IEEE, 2016.

Zoschke, Kai, et al. “Fabrication of application specific integrated passive devices using wafer level packaging technologies.” IEEE Transactions on Advanced Packaging 30.3 (2007): 359-368.

The following foreign patent is incorporated by reference in full:

KR 20170036235 A: Wafer level fan out package and method for manufacturing the same [symbol] and

[symbol]

The Following United States patents and patent applications are incorporated by reference in full:

U.S. Pat. No. 9,704,824 B2: Semiconductor device and method of forming embedded wafer level chip scale packages invented by Yaojian Lin, Pandi C. Marimuthu, II Kwon Shim, and Byung Joon Han

US 20160218020 A1: Method of manufacturing fan out wafer level package Invented by Hongjie Wang, Yibo LIU, Feng Chen, Dongkai Shangguan, and Peng Sun

US 20090087951 A1: Method of manufacturing wafer level package invented by Hyung-Jin Jeon, Sung Yi, Young-Do Kweon, Jong-Yun Lee, Joon-Seok Kang, and Seung-Wook Park

U.S. Pat. No. 6,784,087 B2: Method of fabricating cylindrical bonding structure invented by Jin-Yuan Lee, Chien-Kang Chou, Shih-Hsiung Lin, and Hsi-Shan Kuo

US 2020/0091026 A1: Wafer Level Chip Scale Package Structure invented by Belonio Jr Jesus Mennen, Hu Shou Cheng Eric, Kent Ian, Gutierrez Iii Ernesto, and Li Jerry

U.S. Pat. No. 6,008,070 A: Improved wafer level fabrication and assembly of chip scale packages invented by Farnworth Warren

U.S. Pat. No. 5,323,051 A: Semiconductor wafer level package Invented by Adams Victor J, Bennett Paul T, Hughes Henry G, Scofield Jr Brooks L, and Stuckey Marilyn J

DE 19700734 A1: Sensor production from wafer stack invented by Kurle Juergen, Weiblen Kurt, Pinter Stefan Dr, Muenzel Horst Dr, Baumann Helmut Dr, Schubert Dietrich Dr, Bender Karl, and Lutz Markus

U.S. Pat. No. 6,465,280 B1: In-situ cap and method of fabricating same for an integrated circuit device invented by Martin John R, and Morrison Jr Richard

US 2009/0075431 A1: Wafer level package with cavities for active devices invented by Warren Robert W, Gan Gene, and Lobianco Tony

US 2004/0259325 A1: Wafer level chip scale hermetic package invented by Gan Qing

U.S. Pat. No. 7,169,649 B2: Wafer scale integration of electroplated 3D structures using successive lithography, electroplated sacrificial layers, and flip-chip bonding invented by Rosa Michel A, and Peeters Eric

U.S. Ser. No. 10/600,690 B2 Method for handling a product substrate and a bonded substrate system invented by Meyer-Berg Georg, Von Waechter Claus, Bauer Michael, Doepke Holger, Maier Dominic, Porwol Daniel, and Schmidt Tobias

US 2008/0217748 A1: Low Cost and Low Coefficient of Thermal Expansion Packaging Structures and Processes invented by Knickerbocker John

US 2016/0148909 A1: Semiconductor Packages Having Through Electrodes and Methods of Fabricating the Same invented by Chung Hyun Soo, Kim Jongyeon, Lee In-Young, and Cho Tae-Je

### BRIEF SUMMARY OF THE INVENTION

This invention, Packaging-Level CSP (PL-CSP) processes and apparatus, comprises a process for applying many of the benefits of WL-CSP to standard semiconductor packaging processes resulting in a unique CSP process. The invention reduces the standard packaging process steps by modifying WL-CSP to reduce cost and process time while retaining many of the features of standard multi-layer substrate IC packaging that would be lost with traditional WL-CSP methods. The modified WL-CSP removes or significantly reduces the aforementioned limitations of WL-CSP with the addition of a few layers more commonly associated with standard semiconductor multi-layer packaging.

The method of the present invention comprises plating copper pillars directly onto a wafer; covering the wafer and pillars with dielectric film; a planarization process to expose the pillars and prepare for the next layer; and with the wafer serving as a carrier, adding the final layers to form a complete IC package. In preferred embodiments, a nickel-iron (NiFe) or other metallic layer(s) is/are included to produce a complete IC package that is resistant to warping, and thus, commercially viable across a range of applications.

In at least one exemplary embodiment, the method of the invention comprises taking a wafer, forming at least one die on the surface of the wafer, plating a redistribution layer on the surface of the die, plating at least one copper pillar, covering the wafer and pillars with dielectric film, grinding the film to expose the pillars, plating at least one bonding pad per copper pillar each bond pad electrically connected to a copper pillar, and singlulating the packaged die.

In at least one exemplary embodiment, the bond pads are not spaced more than 0.15 mm apart from each other.

In at least one exemplary embodiment, the invention further comprises plating at least one additional package layer after the grinding step and before plating a bonding pad. At least one additional package layer may contain but is not limited to, an active component, a passive component, or a mems component (which may be active or passive). The passive component may be but is not limited to a magnetic component which in turn may be, but is not limited to, an inductor.

In at least one exemplary embodiment, at least one additional package layer is a thermal expansion control layer, and in at least one exemplary embodiment, the thermal expansion control layer is NiFe (36:64, ±5%) or a similar alloy with a proper coefficient of thermal expansion.

In at least one exemplary embodiment of the invention, a chip comprises a wafer layer, a die on the surface of the wafer, a redistribution layer on the surface of the die and operably connected to the die, a first package layer having at least one copper pillar operably connected to the redistribution layer and being molded in epoxy plastic, at least one bond pad per pillar electrically connected to a corresponding pillar.

In at least one exemplary embodiment, the bonding pads are not spaced farther than 0.15 mm apart.

In at least one exemplary embodiment of the invention, there is at least one additional intervening package layer between the first package layer and the bond pad layer. At least one additional layer may be but is not limited to, containing an active component, a passive component, or specifically a mems device. The passive may be but is not limited to a magnetic component, and the magnetics component may be but is not limited to, an inductor.

Therefore, it can be seen that the method of the invention begins with a wafer die that is electroplated with Cu pillars using a flip-chip Cu pillar process. But instead of depositing solder on the tips of the Cu pillars in preparation for flip chipping, the wafer and Cu pillars are covered with an insulating dielectric film. This is followed by a wafer grind, CMP, or other planarization process performed to expose the copper pillar tips and prepare the surface for the next layer. The process then may add additional layers and the packaging in any manner, with the exception that instead of a carrier, the wafer holder performs the role of the carrier.

The result is a chip packaged in a novel and elegant WL-CSP style. So, the chip incorporates bond pads and has the ability to hold additional layers. These layers may include copper, ceramics, and magnetics necessary for forming integrated passive components that are directly connected to the die and/or PCB. By being able to build additional light-blocking plastic epoxy layers and no longer relying on solder balls, protections against light may be incorporated into the chip design. Bond pads and encapsulating plastic epoxy are also more resistant to vibrations. Further, unique package layers may be formed and added to the package, including, but not limited to, a NiFe (36:64, ±5%) thermal expansion control layer to counteract any systematic warping due to the additional packaging layers. Because the additional layers can be electroplated, a package layer of almost any type may be created.

### BRIEF DESCRIPTION OF THE FIGURES

FIG. 1 is a background general WL-CSP Method.

FIG. 2 is a general overview of the PL-CSP method

FIG. 3 shows how die size might have to be expanded to accommodate a number of solder balls, but not to fit a similar number of bond pads.

FIG. 4 is a wafer—the first step of the PL-CSP method.

FIG. 5 shows a plurality of integrated circuits formed on the wafer.

FIG. 6 shows an intermediary layer built onto the active surface of the wafer.

FIG. 7 shows a series of copper pillars formed on the intermediary layer.

FIG. 8 shows the series of copper pillars now covered in an epoxy plastic layer.

FIG. 9 shows the plastic having been ground down—leaving the upper surface of each copper pillar exposed.

FIG. 10 shows an additional package layer containing an inductor built directly onto the base package layer.

FIG. 11 shows the apparatus of FIG. 10 now singulated.

FIG. 12 shows an additional package layer incorporating a passive built on an initial package layer also containing a passive.

FIG. 13 shows the apparatus of FIG. 12 now having a NiFe (36:64, ±5%) thermal control layer placed between each of the package layers containing passives.

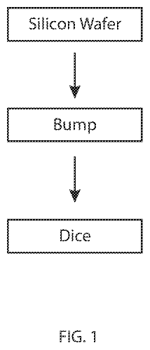

### DETAILED DESCRIPTION OF THE INVENTION

The present invention comprises a unique Chip Scale Package (CSP) method and apparatus. The present invention will be referred to as Package-Level-CSP (PL-CSP).

PL-CSP modifies WL-CSP by innovations that allow additional package layers to be built, some of which can be used to form passive components such as Inductors, Capacitors, and Resistors. This allows for the seamless integration of passive components into multi-layer packaging as opposed to placing already finished discrete passive components.

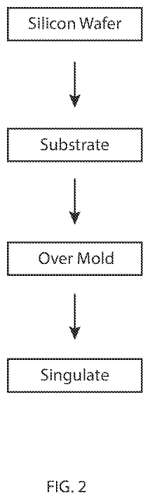

The general flow of the method is demonstrated in FIG. 2. Where an active surface is built on a silicon wafer, followed by building the substrate directly on the active surface of the wafer, over molding, and singulation steps. Additional layers can be built after the initial substrate is built. There is no dicing until the singulation, there is no second wafer or carrier as the substrate is built directly on the active surface of the first wafer, and there is no bumping step—for bumping is not used. There is no special packaging in place of conventional build-up film such as Ajinomoto Build-Up Film. Therefore, in PL-CSP, everything is built on the wafer.

The package of PL-CSP has bonding pads to enable smaller die sizes than would be possible with solder balls. In solder ball limited dice such as WL-CSP, the solder balls set the minimum and maximum dice size. This is problematic as solder balls are larger connectors, and integrated circuit sizes continue to shrink faster than solder ball connectors. With PL-CSP, other styles of connectors can be spaced closer together than solder balls. A 0.22 mm spacing for solder balls is around industry-leading spacing; however, bonding pads can be placed up 0.15 mm together, for example.

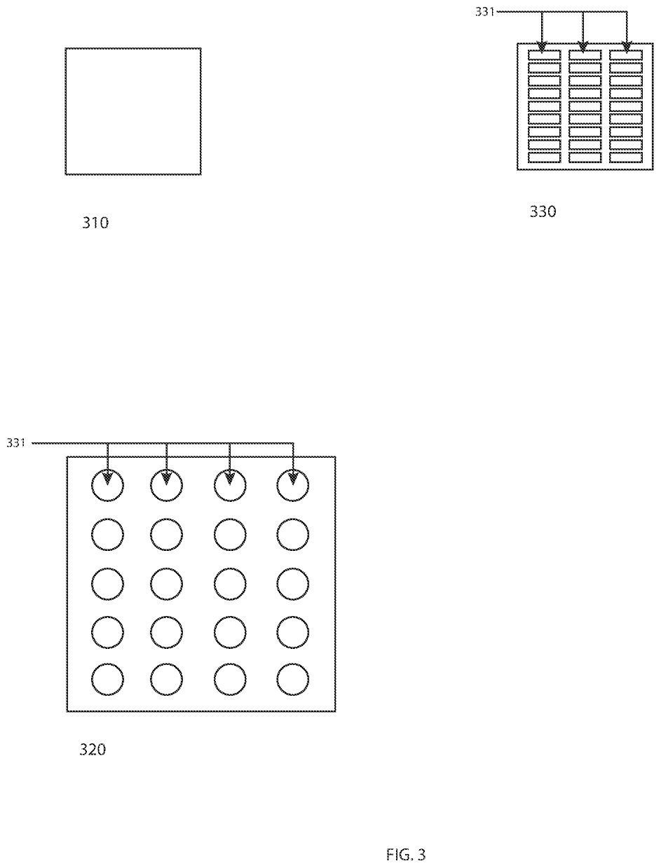

FIG. 3. Shows a die 310. This die 310 would have to be expanded to the size of die 320 if it included rows of solder balls 321. But, with rows of bonding pads 331, the die 310 does need to expand in size even though it includes a similar number of bonding pads 331 as shown by die 330.

By reducing pitch limits and adding CTE control, PL-CSP packaged die can be reliably produced at industrial scales while retaining both integrated circuits and other integrated components, such as passives within the size definitions of CSP.

To build a PL-CSP, a wafer is taken, and dice are built on the wafer. Once the dice are built onto the surface of a wafer, an intermediary layer, for example, a redistribution layer (RDL), is built onto the die.

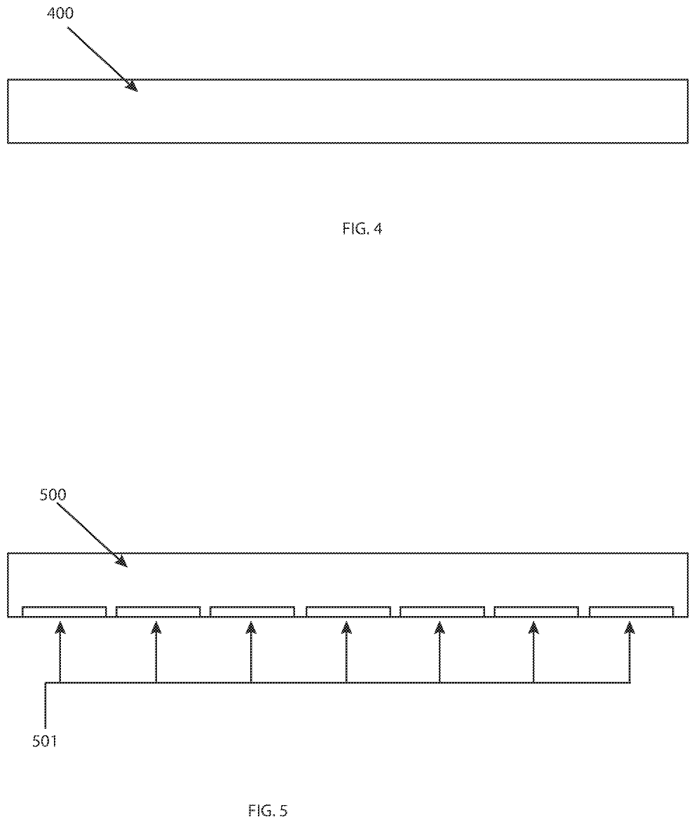

FIG. 4 shows a wafer 400. Taking a wafer is the first step of the PL-CSP method. FIG. 5 shows the second step, which is to form at least one die on the wafer. FIG. 5 shows a plurality of active dice surfaces 501 formed on wafer 500. Tens of thousands of dice may be formed on the wafer.

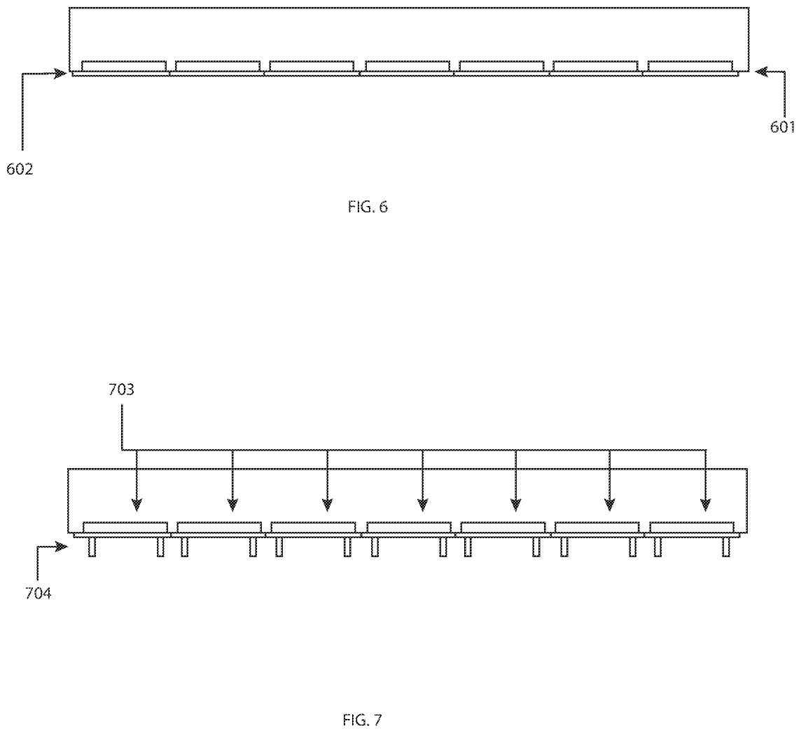

FIG. 6 shows an RDL 602 built onto the active surfaces of wafer 601. Although built simultaneously, there is one specific RDL per active surface.

Upon the RDL, a new package layer may be formed, comprising a series of conductive pillars. These conductive pillars may be copper, but they are not capped as copper posts or bumps but instead are covered in an epoxy film (this package layer may be referred to as the base package layer). A planarization process occurs to set the level of the epoxy plastic to that of the upper surface of the copper pillars, exposing said surfaces. These pillars may be directly connected to a bonding pad or other connectors. However, they need not be directly connected and may instead serve as the base for further packaging layers. This does not involve the formation of a separate substrate which is then mounted or otherwise attached to the wafer or the dice from the wafer. The substrate is built onto the wafer before any singulation occurs.

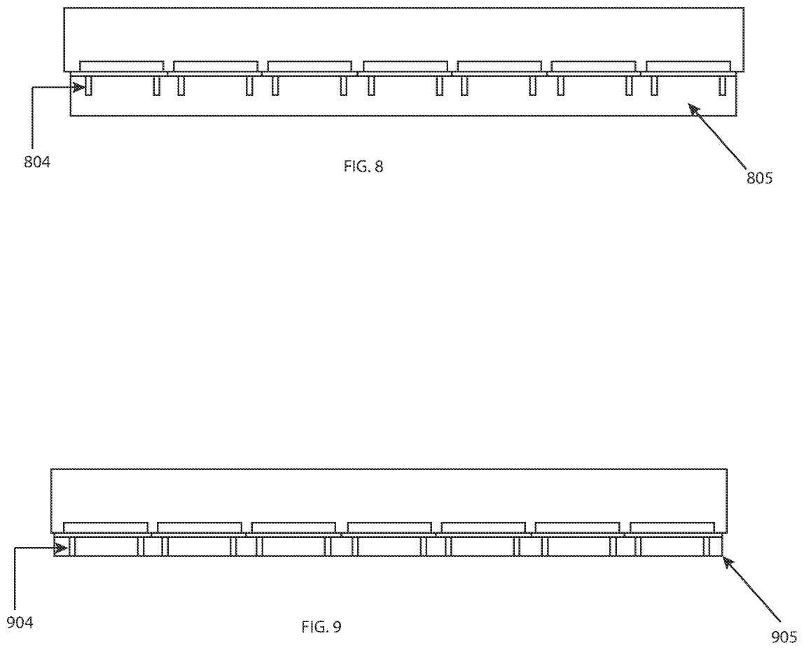

FIG. 7 shows a layer of conductive pillars 704, with a matching series formed on each die 703. These conductive pillars 704 may be copper. FIG. 8 shows an epoxy plastic 805, such as Ajinomoto Build-Up Film, placed over the conductive pillars 804. FIG. 9 shows the after-effects of a planarization process. Here the upper surfaces of the conductive pillars 904 are level with the film 905.

Additional packaging layers may be anything currently integrated into packaging from micro-electric-mechanical systems, active components, or passive components. Of particular interest are passives related to magnetics and especially inductors. The number of layers is only limited by the practical plating constraints. Once the desired layers are formed, a singulation process is undergone to form a prepackaged die.

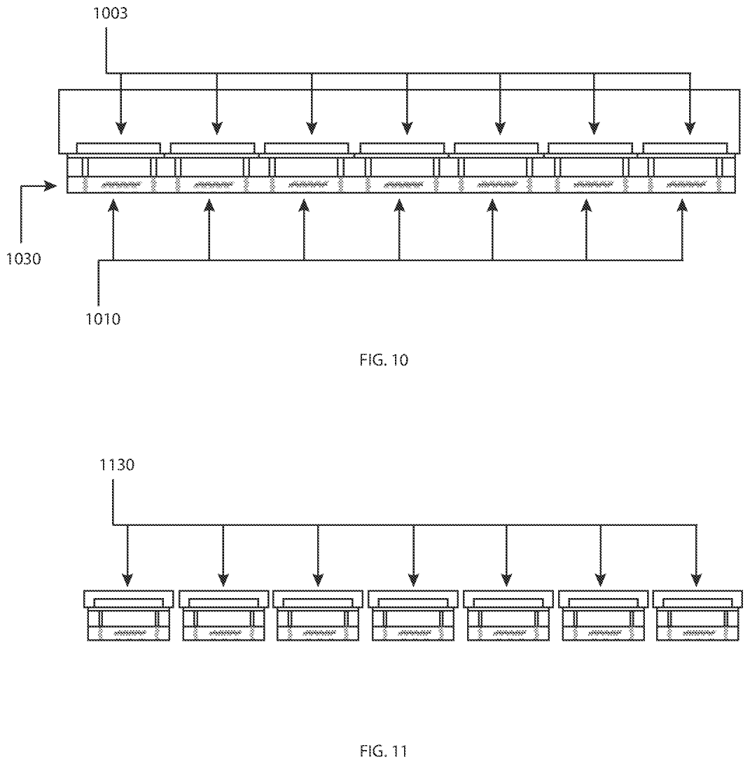

FIG. 10 shows a package layer 1030 with one integrated inductor 1010 per die 1003. FIG. 11 shows the after-effects of a singulation process and a plurality of exemplary embodiments of a singulated PL-CSP die 1013 having an integrated active circuit 501 and an integrated inductor 1106. This singulation process may occur before any of the additional package layers are placed.

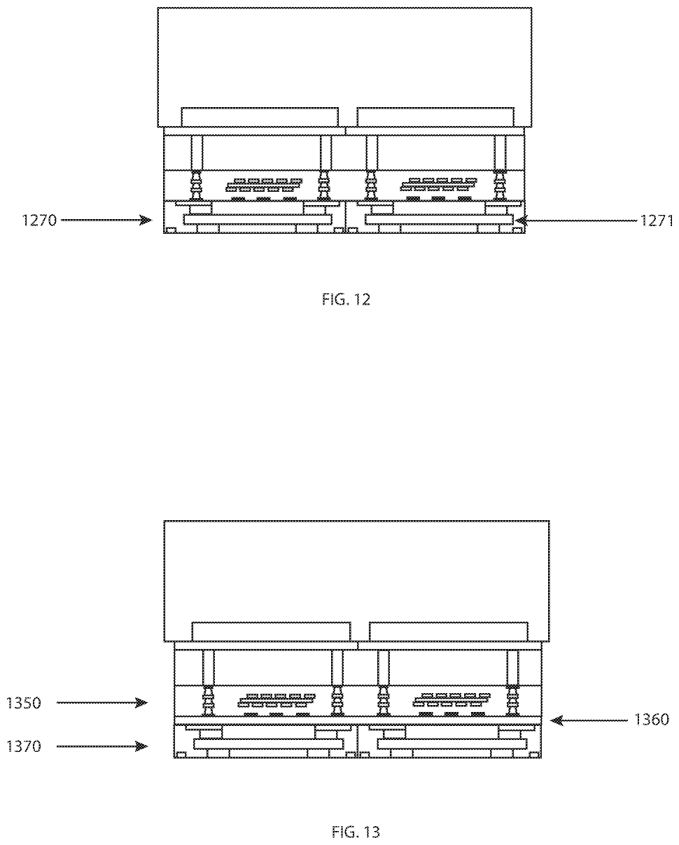

However, a PL-CSP may have many package layers. FIG. 12 shows PL-CSP before singulation, having a second additional package layer 1270. This package layer may contain any component, and for example, component 1271 is an active chip or a passive component.

Apparatuses resulting from several embodiments of the PL-CSP method may be susceptible to warping. The warping occurs because significant copper is present on one side of the PL-CSP with a coefficient of expansion of 16 ppm, which significantly differs from the CTE of silicon which is the material that dominates the other side of the PL-CSP with a coefficient of expansion of 2.6 ppm. Thus, the two sides of the PL-CSP expand at a different rate over temperature, causing bowing which reduces the yield of usable chips when present.

The increase in the amount of copper brought on by integrating magnetic components into the PL-CSP will increase the likelihood of warping due to thermal expansion, given the different warpage rates of silicon and copper.

To consistently achieve packages with this method of the present invention. A thermal expansion control layer (TEC) can be added to the package. It is useful to place the TEC layer after at least one package layer or integrated passive. In at least one exemplary embodiment, the additional package layers alternate between an integrated component and a TEC layer made of NiFe (36:64, ±5%).

FIG. 13 shows a PL-CSP die, pre-singulation, having three additional packaging layers 1350, 1360, and 1370 wherein 1360 is a TEC package layer. This package layer 1360 may be NiFe (36:64, ±5%).

When such a layer has a Coefficient of Thermal Expansion (CTE) similar to the CTE of silicon, such that under most conditions, silicon and the material would not expand at noticeably different rates and has a high enough tensile strength—the layer can be used to hold the expansion of surrounding layers in place—keeping the surrounding layers in check with silicon—without the need to step the CTE of the package. One such material that can achieve these results is NiFe (36:64, ±5%).

The use of NiFe (36:64, ±5%) increases the yield of the invention and typically is formed as a thin layer of packaging. Thin NiFe (36:64, ±5%) layering does not affect the electrical or magnetic properties of the components. This is contrary to popular belief, which holds that adding additional metal layers, especially a nickel-iron alloy such as NiFe (36:64, ±5%), to a magnetics component will negatively affect the performance of the component. This is not true, and the incorporation of NiFe (36:64, ±5%) further allows for usable yields of CSP, which include a die and integrated passives into a single multi-layer package manufactured for fewer steps and lower costs than even WL-CSP.

In at least one exemplary embodiment, NiFe (36:64, ±5%) is unnecessary, and in further embodiments, even if used it need not be given its own layer, but incorporated into other package layers.

In at least one exemplary embodiment of the present invention, insulating films; the design of the multiple layers of the packaging; the thickness of the dielectric; the use of NiFe (36:64, ±5%); NiFe 35-65; and/or other materials that closely match the CTE of silicon; and the design of the Cu traces and interconnects can reduce the warpage related to the difference in CTE among the package layers. However, in at least one exemplary embodiment, CTE is not especially controlled by any means.

With the addition of NiFe (36:64, ±5%), nickel-iron (NiFe) 35-65, and/or other materials that closely match the CTE of silicon the warping is significantly reduced as the tensile strength of, for example, NiFe 35-65 is strong enough to limit the expansion of copper due to an increase in temperature so that copper's expansion more closely aligns with silicon. In the preferred embodiment, this NiFe layer or layers are thin enough not to significantly interfere with the magnetic properties of magnetic core components to otherwise prevent the core from achieving its desired purposes.

The drawings and figures show multiple embodiments and are intended to be descriptive of particular embodiments but not limited with regards to the scope or number, or style of the embodiments of the invention. The invention may incorporate a myriad of styles and particular embodiments. All figures are prototypes and rough drawings: the final products may be refined by one of the ordinary skills in the art. Nothing should be construed as critical or essential unless explicitly described as such. Also, the articles “a” and “an” may be understood as “one or more.” Where only one item is intended, the term “one” or other similar language is used. Also, the terms “has,” “have,” “having,” or the like are intended to be open-ended terms. In any such item incorporated by reference in any section of the provisional patent application where there is a definition contradictory to the definition laid out in the provisional patent application in material fully integrated into the application, the definition that is fully integrated into the text of the patent will control the meaning for the present invention.

1. I claim a method of producing a Package-Level Chip Scale Package comprising
Taking a wafer;
Forming at least one dice on a surface of the wafer;
Forming an intermediary layer on a surface of the die;
Forming at least one conductive pillar;
Depositing an epoxy plastic over the conductive pillar layer to a thickness exceeding the height of the conductive pillar;
Grinding excess epoxy plastic to expose an upper surface of the conductive pillar;
Forming at least one bonding pad per copper pillar being electrically connected to its corresponding pillar; and
Singulating the packaged die.

2. The method of claim 1, wherein the bond pads are not spaced more than 0.15 mm apart from each other

3. The method of claim 1, further comprising forming at least one additional package layer after grinding and before plating a bond pad, the bond pads now being operably placed on the last additional package layer formed, according to the connections of the last package layer.

4. The method of claim 3, wherein at least one additional package layer contains an active component

5. The method of claim 3, wherein at least one additional package layer contains at least one passive component

6. The method of claim 3, wherein at least one package component contains a mems component

7. The method of claim 3, wherein at least one package layer is a thermal expansion control layer

8. The method of claim 7, wherein the thermal expansion control layer is NiFe (36:64, ±5%)

9. The method of claim 3, wherein the passive component is a magnetic component

10. The method of claim 9, wherein the magnetic component is an inductor

11. I claim a Package-Level Chip Scale Package comprising;
A wafer layer;
A die on a surface of the wafer;
An intermediary layer on a surface of the die and operably connected to the die;
A base package layer having at least one conductive pillar operably connected to the redistribution layer and being molded in epoxy plastic; and
At least one bond pad per pillar electrically connected to a corresponding conductive pillar.

12. The Package-Level Chip Scale Package of claim 1 wherein the bond pads are not spaced more than 0.15 mm apart from each other.

13. The Package-Level Chip Scale Package of claim 11, further comprising at least one additional package layer after the base package layer, the bond pads now on the last additional package layer formed, according to the copper connections of the last package layer.

14. The Package-Level Chip Scale Package of claim 13, wherein at least one package layer contains an active component.

15. The Package-Level Chip Scale Package of claim 13, wherein at least one package component contains a mems component.

16. The Package-Level Chip Scale Package of claim 13, wherein at least one package layer contains at least one passive component.

17. The Package-Level Chip Scale Package of claim 16, wherein the passive component is a magnetic component.

18. The Package-Level Chip Scale Package of claim 17, wherein the magnetic component is an inductor

19. The Package-Level Chip Scale Package of claim 13, wherein at least one additional package layer is a thermal expansion control layer.

20. The Package-Level Chip Scale Package of claim 8, wherein the thermal expansion control layer is NiFe (36:64, ±5%).
